(19) United States
(12) Patent Application Publication
(10) Pub. No.: US 2025/0031387 A1
(43) Pub. Date: Jan. 23, 2025

(54) METHOD OF FORMING CAPACITOR STRUCTURE

(71) Applicant: NANYA TECHNOLOGY CORPORATION, New Taipei City (TW)

(72) Inventor: Hui-Lin CHEN, Keelung City (TW)

(21) Appl. No.: 18/224,609

(22) Filed: Jul. 21, 2023

(51) Int. Cl. H10B 99/00

(52) U.S. Cl. CPC H10B 99/14

(57) ABSTRACT

A method of forming a capacitor structure includes a number of operations. A single carbon film is deposited over tops of bottom electrode plates. The single carbon film is patterned. The bottom electrode plates are etched based on the single carbon film after the single carbon film is patterned. The single carbon film is removed after the bottom electrode plates are etched. A dielectric layer is formed over the bottom electrode plates. A plurality of top electrode plates is formed over the dielectric layer and aligned with the bottom electrode plates.

### BACKGROUND

### Field of Invention

The present disclosure relates to methods of forming capacitor structure.

### Description of Related Art

A storage structure may include one or more capacitors. As critical dimension (CD) of the storage structure shrinks, more supporting strength is for the storage structure to keep the overall structure strength steady. Less stress formation process is to avoid cracks and damage to the storage structure.

Accordingly, how to provide a method of forming the capacitance structure of the storage structure including capacitor array under a low stress condition is a subject solved by those in the industry.

### SUMMARY

An aspect of the present disclosure is related to a method of forming a capacitor structure.

According to one or more embodiments of the present disclosure, a method of forming a capacitor structure includes a number of operations. A single carbon film is deposited over tops of bottom electrode plates. The single carbon film is patterned. The bottom electrode plates are etched based on the single carbon film after the single carbon film is patterned. The single carbon film is removed after the bottom electrode plates are etched. A dielectric layer is formed over the bottom electrode plates. A plurality of top electrode plates is formed over the dielectric layer and aligned with the bottom electrode plates.

In one or more embodiments of the present disclosure, the single carbon is deposited film by a plasma-enhanced chemical vapor deposition process at a temperature in a range between 600° C. and 650° C.

In one or more embodiments of the present disclosure, the method further includes numbers of operations. A first dielectric anti-reflective layer is deposited over the single carbon film. A second dielectric anti-reflective layer directly is deposited over the first dielectric anti-reflective layer.

In some embodiments, the first dielectric anti-reflective layer and the second dielectric anti-reflective layer are deposited by chemical vapor deposition processes.

In some embodiments, the first dielectric anti-reflective layer and the second dielectric anti-reflective layer are silicon oxynitride and have different compositions of oxygen and silicon.

In some embodiments, the method further includes numbers of operations. An anti-reflective coating is formed over the second dielectric anti-reflective layer. A photoresist layer is formed over the anti-reflective coating, wherein the anti-reflective coating and the photoresist layer are formed by coating processes, and patterning the single carbon film includes etching the single carbon film by the photoresist layer.

In one or more embodiments of the present disclosure, the bottom electrode plates are formed within a stack of nitride layers and oxide layers. Etching the bottom electrode plates includes etching the nitride layers and the oxide layers to a top surface of the lowest nitride layer.

In some embodiments, an etch selectivity of the single carbon film and the oxide layers is equal to or greater than 30.

In one or more embodiments of the present disclosure, each of the bottom electrode plates has a U-shape profile with a bottom portion connected to a conductive layer, etching the bottom electrode plates includes etching sidewall portions of immediately-adjacent two of the bottom electrode plates to define a common bottom electrode region.

An aspect of the present disclosure is related to a method of forming a capacitor structure.

According to one or more embodiments of the present disclosure, a method of forming a capacitor structure includes a number of operations. A carbon film is deposited over a stack of nitride layers and oxide layers and a plurality of bottom electrode plates within the stack of the nitride layers and the oxide layers, wherein the carbon film has compressive stress. The carbon film is patterned. The bottom electrode plates and the stack of the nitride layers and the oxide layers are etched based on the carbon film after the carbon film is patterned. The carbon film is removed after the bottom electrode plates and the stack of the nitride layers and the oxide layers are etched. The oxide layers are removed. A dielectric layer is formed over the bottom electrode plates. A plurality of top electrode plates is formed over the dielectric layer and aligned with the bottom electrode plates.

In one or more embodiments of the present disclosure, the carbon film is deposited by a plasma-enhanced chemical vapor deposition process at a temperature in a range between 600° C. and 650° C.

In one or more embodiments of the present disclosure, the method further includes number of operations. A first dielectric anti-reflective layer is deposited over the carbon film. A second dielectric anti-reflective layer is deposited directly over the first dielectric anti-reflective layer.

In some embodiments, the method further includes numbers of operations. An anti-reflective coating is formed over the second dielectric anti-reflective layer. A photoresist layer is formed over the anti-reflective coating, wherein the anti-reflective coating and the photoresist layer are formed by coating processes, and patterning the carbon film includes etching the carbon film by the photoresist layer.

In one or more embodiments of the present disclosure, an etch selectivity of the carbon film and the oxide layers is equal to or greater than 30.

In one or more embodiments of the present disclosure, each of the bottom electrode plates is a hollow tube with a U-shape profile, and each of the top electrode plates is filled with immediate-adjacent two of the bottom electrode plates.

An aspect of the present disclosure is related to a method of forming a capacitor structure.

According to one or more embodiments of the present disclosure, a method of forming a capacitor structure includes a number of operations. A carbon film is deposited over a plurality of bottom electrode plates. A first dielectric anti-reflective layer is deposited over the carbon film. A second dielectric anti-reflective layer is deposited directly over the first dielectric anti-reflective layer, wherein the first dielectric anti-reflective layer and the second dielectric anti-reflective layer have different compositions of oxygen and silicon. An anti-reflective coating is formed over the second dielectric anti-reflective layer. A photoresist layer is formed over the anti-reflective coating. The carbon film is patterned by the photoresist layer. The bottom electrode plates are etched based on the carbon film after the carbon film is etched. A dielectric layer is formed over the bottom electrode plates after the bottom electrode plates are etched. A plurality of top electrode plates is formed over the dielectric layer and aligned with the bottom electrode plates.

In one or more embodiments of the present disclosure, each of the top electrode plates is formed over a common bottom electrode region across at least two of the bottom electrode plates.

In one or more embodiments of the present disclosure, the anti-reflective coating and the photoresist layer are formed by coating processes.

In one or more embodiments of the present disclosure, depositing the carbon film over the bottom electrode plates includes depositing the carbon film over a stack of oxide layers and nitride layers around the bottom electrode plates.

In one or more embodiments of the present disclosure, the carbon film is deposited by a plasma-enhanced chemical vapor deposition process at a temperature in a range between 600° C. and 650° C.

In summary, in one or more embodiments of the present disclosure, less numbers of carbon films are used as hard masks for etching under-layer structures. Less stress accumulation phenomenon appears on the under-layer structure under the single carbon film, and it avoids cracks and damage for the under-layer structure under the single carbon film.

It is to be understood that both the foregoing general description and the following detailed description are by examples, and are intended to provide further explanation of the disclosure as claimed.

### BRIEF DESCRIPTION OF THE DRAWINGS

The advantages of the present disclosure are to be understood by the following exemplary embodiments and with reference to the attached drawings. The illustrations of the drawings are merely exemplary embodiments and are not to be considered as limiting the scope of the disclosure.

FIG. 1 illustrates a schematic cross-section view of an intermediated structure of forming a capacitor structure according to one or more embodiments of the present disclosure;

FIG. 2A illustrates a schematic top view of a plurality of bottom electrode plates according to one or more embodiments of the present disclosure;

FIG. 2B illustrates a schematic cross-section view of FIG. 2A;

FIG. 3 illustrates a schematic cross-section view of forming a carbon film over the bottom electrode plates according to one or more embodiments of the present disclosure;

FIG. 4 illustrates a schematic cross-section view of forming dielectric anti-reflective layers over the carbon film according to one or more embodiments of the present disclosure;

FIG. 5 illustrates a schematic cross-section view of forming an anti-reflective coating and a photoresist layer over the anti-reflective coatings according to one or more embodiments of the present disclosure;

FIG. 6 illustrates a schematic cross-section view of etching the dielectric anti-reflective layers according to one or more embodiments of the present disclosure;

FIG. 7 illustrates a schematic cross-section view of patterning the carbon film according to one or more embodiments of the present disclosure;

FIG. 8 illustrates a schematic cross-section view of removal of the photoresist layers, the anti-reflective coating and the dielectric anti-reflective layers according to one or more embodiments of the present disclosure;

FIGS. 9A and 9B illustrate a schematic top view and a cross-section view of etching the bottom electrode plates, the nitride layer and the oxide layers by the carbon film according to one or more embodiments of the present disclosure;

FIG. 10 illustrates a schematic cross-section view of removal of the carbon films and the oxide layers according to one or more embodiments of the present disclosure;

FIG. 11 illustrates a schematic cross-section view of forming a high-k dielectric layer over the bottom electrode plates according to one or more embodiments of the present disclosure;

FIG. 12 illustrates a schematic cross-section view of forming a plurality of top electrode plates over the high-k dielectric layer according to one or more embodiments of the present disclosure; and

FIG. 13 illustrates a flow chart of a method of forming a capacitor structure according to one or more embodiments of the present disclosure.

### DETAILED DESCRIPTION

Reference will now be made in detail to the embodiments of the present disclosure, examples of which are illustrated in the accompanying drawings. Wherever possible, the same reference numbers are used in the drawings and the description to refer to the same or like parts.

In addition, terms used in the specification and the claims generally have the usual meaning as each terms are used in the field, in the context of the disclosure and in the context of the particular content unless particularly specified. Some terms used to describe the disclosure are to be discussed below or elsewhere in the specification to provide additional guidance related to the description of the disclosure to specialists in the art.

Phrases “first,” “second,” etc., are solely used to separate the descriptions of elements or operations with same technical terms, not intended to be the meaning of order or to limit the disclosure.

Secondly, phrases “comprising,” “includes,” “provided,” and the like, used in the context are all open-ended terms, i.e. including but not limited to.

Further, in the context, “a” and “the” can be generally referred to one or more unless the context particularly requires. It will be further understood that phrases “comprising,” “includes,” “provided,” and the like, used in the context indicate the characterization, region, integer, step, operation, element and/or component it stated, but not exclude descriptions it stated or additional one or more other characterizations, regions, integers, steps, operations, elements, components and/or groups thereof.

As critical dimension (CD) shrinks, a storage structure needs more supporting strength by lattice nitride to keep the overall structure strength steady. Due to etch selectivity, in one or more embodiments of the present disclosure, instead of a stack of nitride and oxide, one or more layers of carbon film and dielectric anti-reflective layers can be used to form a capacitor structure in the storage structure. In one or more embodiments of the present disclosure, less numbers of layers are used to reduce stress so as to avoid crack and film peeling phenomenon on the formed capacitor structure.

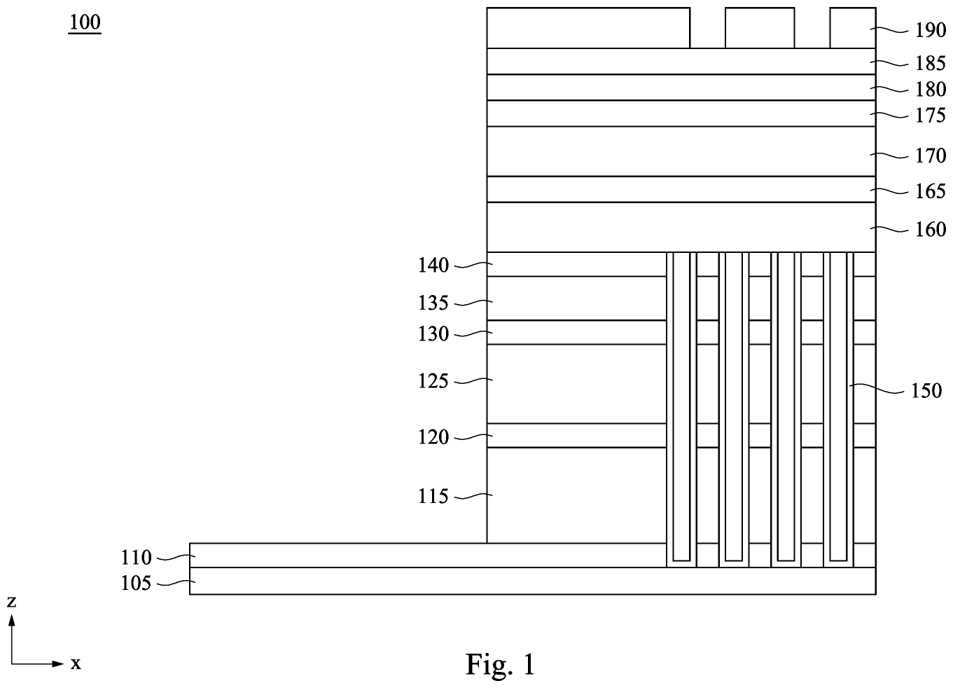

Reference is made to FIG. 1. FIG. 1 illustrates a schematic cross-section view of an intermediated structure 100 of forming a capacitor structure according to one or more embodiments of the present disclosure, wherein two layers of carbon films 160 and 170 are formed in the intermediated structure 100.

In one or more embodiments of the present disclosure, a conductive layer 105 is formed over a substrate. The substrate is, for example, silicon substrate or other suitable semiconductor substrate. For the sake of clarity, the substrate under the conductive layer 105 is not illustrated in FIG. 1. In one or more embodiments of the present disclosure, the conductive layer 105 includes metal, for example, tungsten or other suitable metal material. As shown in FIG. 1, the conductive layer 105 extends in the direction x.

As illustrated in FIG. 1, a nitride layer 110 is over the conductive layer 105. A top surface of the conductive layer 105 is covered by the nitride layer 110 such that the nitride layer 110 protects the conductive layer 105 from damage. An oxide layer 115 is over the nitride layer 110. A nitride layer 120 is over the oxide layer 115. An oxide layer 125 is over layer the nitride layer 120. A nitride layer 130 is over the oxide layer 125. An oxide layer 135 is over the nitride layer 130. A nitride layer 140 is over the oxide layer 135. The nitride layers 110, 120, 130, 140 and the oxide layer 115, 125 and 135 can be regarded as a semiconductor storage stack over the conductive layer 105. A plurality of bottom electrode plates 150 is formed in the semiconductor storage stack of the nitride layers 110, 120, 130, 140 and the oxide layer 115, 125 and 135.

As shown in FIG. 1, the bottom electrode plates 150 are hollow tubes extending along the direction z. The bottom electrode plates 150 extend through the nitride layers 110, the oxide layer 115, the nitride layers 120, the oxide layer 125, the nitride layers 130, the oxide layer 135 and the nitride layers 140 in order in the direction z and extend to the conductive layer 105. In one or more embodiments of the present disclosure, the nitride layers 110, 120, 130, 140 can be regarded as support layers used to support the bottom electrode plates 150. The oxide layers 115, 125 and 135 can be regarded as support sacrificial layers and removed in further process.

In one or more embodiments of the present disclosure, the nitride layers 110, 120, 130, 140 include titanium nitride or silicon nitride. In one or more embodiments of the present disclosure, the oxide layer 115 includes boro-phospho-silicate-glass (BPSG). In one or more embodiments of the present disclosure, the oxide layer 125 includes tetraethoxysilane (TEOS) oxide. In one or more embodiments of the present disclosure, material of the bottom electrode plates 150 can include conductive material, for example, metal material.

In the schematic cross-section view of FIG. 1, each of the bottom electrode plates 150 is a hollow tube having a U-shape profile, and the bottoms of the bottom electrode plates 150 are connected to the same conductive layer 105.

After the bottom electrode plates 150 are formed in the semiconductor storage stack of the nitride layers 110, 120, 130, 140 and the oxide layer 115, 125 and 135, two layers of hard mask layers are formed over a top surface of the nitride layer 140 and tops of the bottom electrode plates 150. As shown in FIG. 1, a hard mask layer including a carbon film 160 and a dielectric anti-reflective layer 165 (i.e., dielectric anti-reflective coating layer, also named as DARC layer) over the carbon film 160 is over the top surface of the nitride layer 140 and the tops of the bottom electrode plates 150, and another hard mask layer including a carbon film 170 and a dielectric anti-reflective layer 175 over the carbon film 170 is over the dielectric anti-reflective layer 165.

In one or more embodiments of the present disclosure, the carbon film 160 is formed by a deposited process. For example, the carbon film 160 is deposited over the top surface of the nitride layer 140 by a plasma-enhanced chemical vapor deposition (PECVD) process. Propene (C₃H₆) is provided and reacts with plasma to deposit the carbon film 160. In some embodiments of the present disclosure, the carbon film 160 is deposited at temperature near 550° C., and the formed carbon film 160 has a density of 1.71 g/cm³, stress of +231 MPa and modulus of 126 GPa. It is noted that the plus sign of stress means that the carbon film 160 may apply tensile stress to under-layer structure. Etch selectivity of carbon film 160 and the oxide layers 115, 125 and 135 may describe an etch rate ratio between the carbon film 160 and one of the oxide layers 115, 125 and 135. For an etching process of the oxide layers 115, 125 and 135 (e.g., using an etchant for the oxide layers 115, 125 and 135), an etch selectivity, which is a ratio of an etch rate of the carbon film 160 to an etch rate of the oxide layers 115, 125 and 135, can be 15.

After the carbon film 160 is formed, the dielectric anti-reflective layer 165 is then deposited over the carbon film 160 by a CVD process. In some embodiments of the present disclosure, the dielectric anti-reflective layer 165 is SiON film deposited over the carbon film 160 by a reaction of SiH₄ gas and N₂O gas.

The carbon film 170 can be deposited over the dielectric anti-reflective layer 165 by a PECVD process similar to the PECVD process of the carbon film 160 and have similar density, stress, modulus and etch selectivity. The dielectric anti-reflective layer 175 is then deposited over the carbon film 170 by a CVD process similar to the CVD process of the dielectric anti-reflective layer 165.

A photoresist layer 190 is then formed over the dielectric anti-reflective layer 175. A photo hard mask 185 is formed between the dielectric anti-reflective layer 165 and the photoresist layer 190. An under-layer 180 is under the photo hard mask 185. In one or more embodiments of the present disclosure, the under-layer 180, the photo hard mask 185 and the photoresist layer 190 are formed by coating processes.

The carbon films 160 and 170 of the hard mask layers can be patterned by the photoresist layer 190, the bottom electrode plates 150 and the semiconductor storage stack of the nitride layers 110, 120, 130, 140 and the oxide layer 115, 125 and 135 can be etched based on the patterned carbon films 160 and 170.

In one or more embodiments of the present disclosure, stress accumulation of the carbon films 160 and 170 would cause structure crack and damage the bottom electrode plates 150. Abnormal profiles caused by the stress accumulation would appear in the formed capacitor structure. In one or more embodiments of the present disclosure, a single layer of carbon film can be regarded as a hard mask layer used for etching the bottom electrode plates and oxide layer, and the single layer of carbon film can have low stress and improve stress accumulation phenomenon.

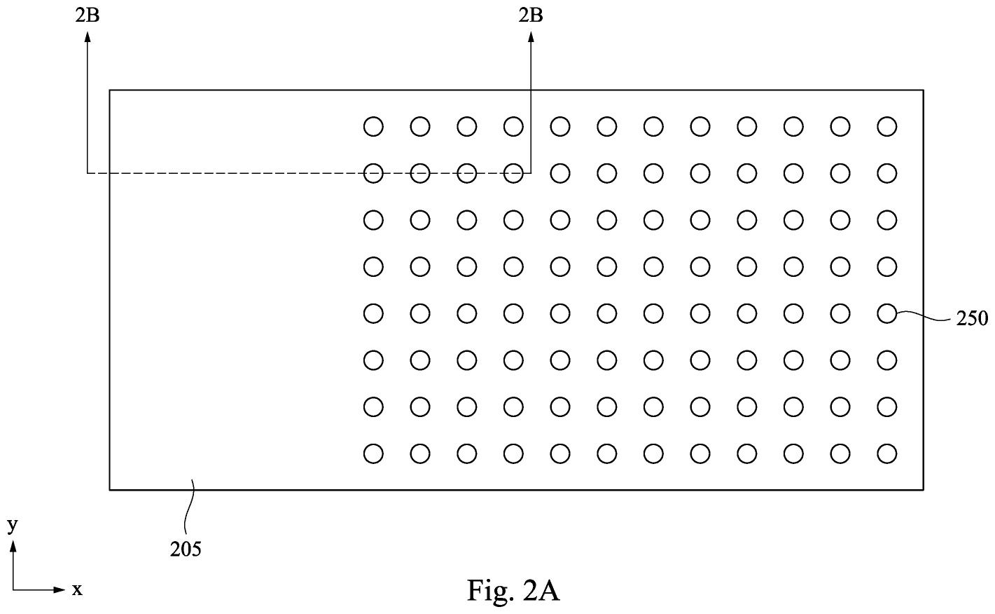

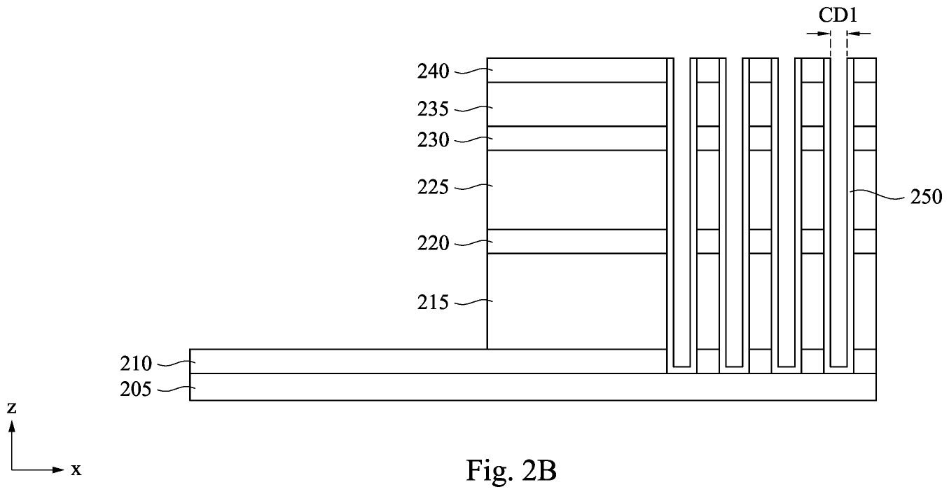

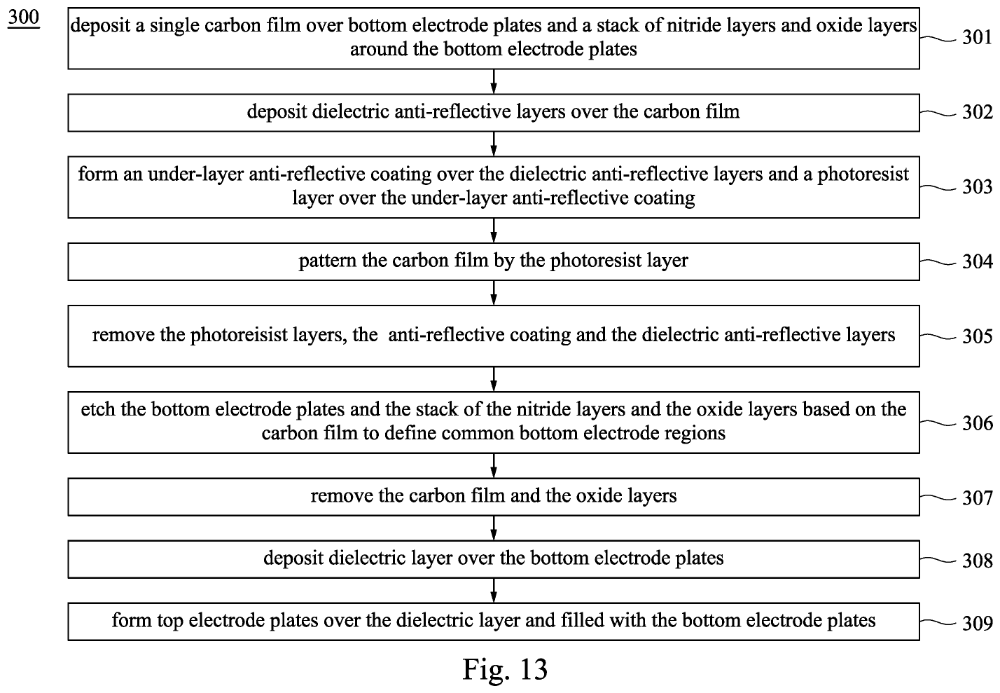

Reference is made to FIGS. 2A-12 and FIG. 13. FIGS. 2A-12 illustrate schematic top views and schematic cross-section views of forming a capacitor structure 200. FIG. 13 illustrates a flow chart of a method 300 of forming the capacitor structure 200 according to one or more embodiments of the present disclosure.

FIG. 2A illustrates a schematic top view of a plurality of bottom electrode plates 250 according to one or more embodiments of the present disclosure. FIG. 2B illustrates a schematic cross-section view of FIG. 2A, wherein FIG. 2B illustrates the cross-section view along a line across an edge of an array of the bottom electrode plates 250 in the direction x.

As shown in FIG. 2A, a plurality of bottom electrode plates 250 is formed over a conductive layer 205. For the sake of clarity, numbers of layers are not illustrated in FIG. 2A. In FIG. 2A, the bottom electrode plates 250 are equally spaced in the direction x and the direction y and form an array. FIG. 2B illustrates a cross-section view of an edge of the array of bottom electrode plates 250.

In FIG. 2B, a semiconductor storage stack of semiconductor layers is formed over the conductive layer 205 and surrounds the bottom electrode plates 250. The semiconductor storage stack includes a nitride layer 210 over the conductive layer 205, an oxide layer 215 over the nitride layer 210, a nitride layer 220 over the oxide layer 215, an oxide layer 225 over the nitride layer 220, a nitride layer 230 over the oxide layer 225, an oxide layer 235 over the nitride layer 230 and a nitride layer 240 over the oxide layer 235. A top surface of the conductive layer 205 is covered by the nitride layer 210. A top surface of the nitride layer 210 is exposed.

As shown in FIG. 2B, each of the bottom electrode plates 250 is a hollow tube having a U-shape profile, and the bottom of the U-shape profiles of the bottom electrode plates 250 are connected to the same conductive layer 205. The bottom portions of the bottom electrode plates 250 extend through the nitride layers 210, the oxide layer 215, the nitride layers 220, the oxide layer 225, the nitride layers 230, the oxide layer 235 and the nitride layers 240 in order in the direction z and extend to the conductive layer 205. The bottom electrode plates 250 have open tops with lengths CD1 in the direction x. The lengths CD1 can be regarded as observable critical dimensions of the bottom electrode plates 250.

In one or more embodiments of the present disclosure, the conductive layer 205 includes metal, for example, tungsten or other suitable metal material. In one or more embodiments of the present disclosure, the oxide layer 215 includes BPSG. In one or more embodiments of the present disclosure, the oxide layer 225 includes TEOS oxide. In one or more embodiments of the present disclosure, material of the bottom electrode plates 250 can include conductive material, for example, metal material.

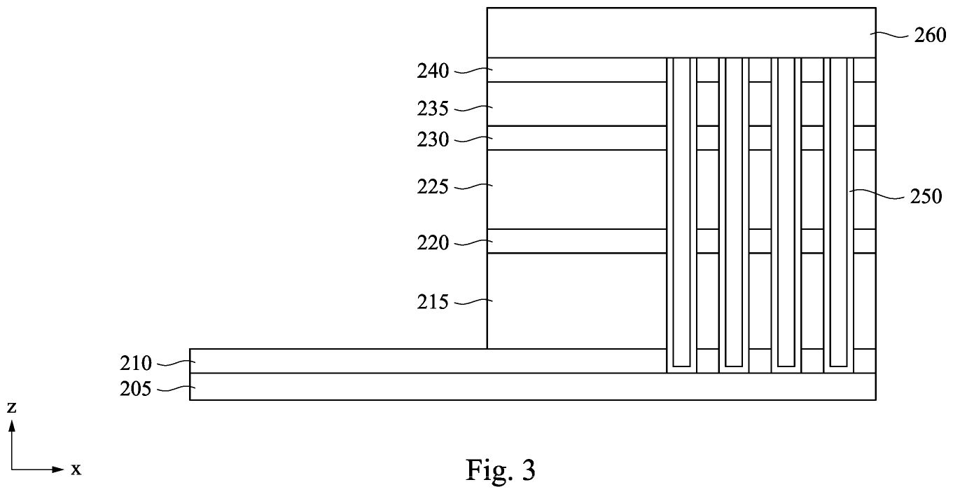

Reference is made to FIG. 3 and FIG. 13. In operation 301, a single carbon film 260 is formed over bottom electrode plates 250 and the stack of the nitride layers 110, 120, 130, 140 and the oxide layers 115, 125 and 135 around the bottom electrode plates 250. FIG. 3 illustrates a schematic cross-section view of forming a carbon film 260 over the bottom electrode plates 250 according to one or more embodiments of the present disclosure.

In one or more embodiments of the present disclosure, the carbon film 260 is formed by a deposited process. For example, the carbon film 260 is deposited over the top surface of the nitride layer 240 by a plasma-enhanced chemical vapor deposition (PECVD) process. For details, during the PECVD process of the carbon film 260, propene (C₃H₆) is provided and reacts with plasma to deposit the carbon film 260.

In some embodiments of the present disclosure, the carbon film 260 is deposited at a temperature in a range between 600° C. and 650° C. For example, the carbon film 260 is deposited at a temperature of 325° C., and the formed carbon film 260 has a density of 1.93 g/cm³, stress of −50 MPa and modulus of 162 GPa. It is noted that the negative sign of stress means that the carbon film 260 may apply compressive stress to under-layer structure, for example, the bottom electrode plates 250.

The carbon film 260 deposited under a high temperature may have great density. A difference between the carbon film 160 or 170 as illustrated in FIG. 1 and deposited under 550° C. and the carbon film 260 deposited under 625° C. is that the density of the carbon film 260 is greater than the density of the carbon film 160 or 170. The carbon film 260 having great density may also have great modulus and etch selectivity with respect to oxide. Etch selectivity of carbon film 260 and the oxide layers 215, 225 and 235 may describe an etch rate ratio between the carbon film 260 and one of the oxide layers 215, 225 and 235. For example, in one or more embodiments of the present disclosure, for an etching process of the oxide layers 215, 225 and 235 (e.g., using an etchant for the oxide layers 215, 225 and 235), an etch selectivity, which is a ratio of an etch rate of the carbon film 260 to an etch rate of the oxide layers 215, 225 and 235, can be 30.

A difference between the carbon film 160 as illustrated in FIG. 1 and deposited under 550° C. and the carbon film 260 deposited under 625° C. is that the stress of the carbon film 260 is different from the stress of the carbon film 160 or 170. A magnitude of the stress of the carbon film 260 is less than a magnitude of the stress of the carbon film 160 or 170. The direction of the stress of the carbon film 260 is opposite to the direction of the stress of the carbon film 160 or 170. The carbon film 260 has great density and great modulus so that the carbon film 260 has fewer extending portions and may not apply tensile stress to the under-layer structure. The carbon film 260 has less compressive stress to avoid crack or damage of under-layer structure.

In one or more embodiments of the present disclosure, carbon may be deposited inside the bottom electrode plates 250 during deposition of the carbon film 260. The carbon deposited inside the bottom electrode plates 250 may be removed in a further removal process for the carbon film 260.

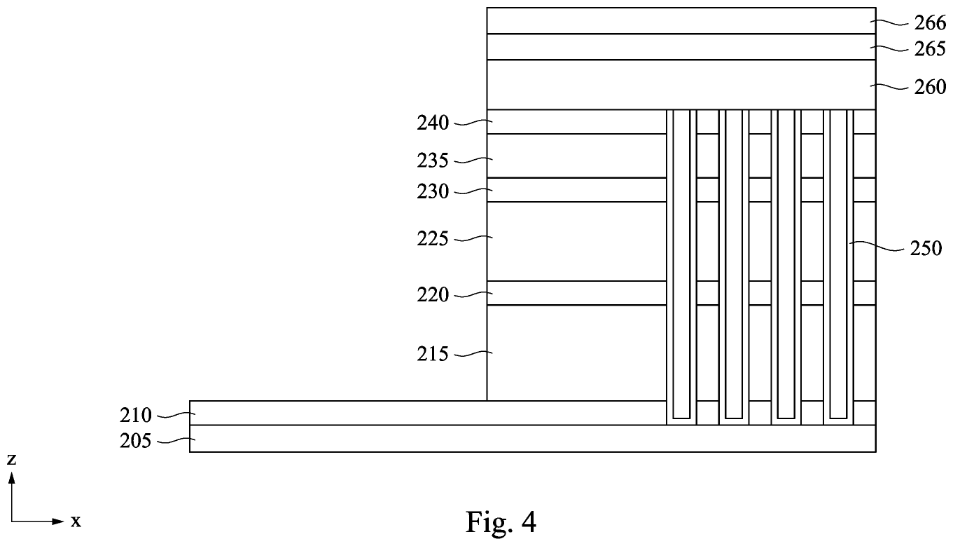

Reference is made to FIG. 4 and FIG. 13. In operation 302, dielectric anti-reflective layers 265 and 266 are deposited over the carbon film 260. FIG. 4 illustrates a schematic cross-section view of forming the dielectric anti-reflective layers 265 and 266 over the carbon film 260 according to one or more embodiments of the present disclosure.

As shown in FIG. 4, after the carbon film 260 is formed, the dielectric anti-reflective layer 265 is deposited directly over the carbon film 260 by a CVD process. In some embodiments of the present disclosure, the dielectric anti-reflective layer 265 may be SiON film deposited over the carbon film 260 by a reaction of SiH₄ gas and N₂O gas. The dielectric anti-reflective layer 266 is then deposited directly over the dielectric anti-reflective layer 265. Similarly, the dielectric anti-reflective layer 266 may be SiON film deposited directly over dielectric anti-reflective layer 265 by a reaction of SiH₄ gas and N₂O gas. In one or more embodiments of the present disclosure, the dielectric anti-reflective layers 265 and 266 have different compositions of oxygen and silicon. For example, the dielectric anti-reflective layer 265 may be a Si-rich anti-reflective layer and the dielectric anti-reflective layer 266 may be an O-rich anti-reflective layer. In one or more embodiments of the present disclosure, compositions of oxygen and silicon for the dielectric anti-reflective layers 265 and 266 are adjusted based on the design of photolithography for the carbon film 260.

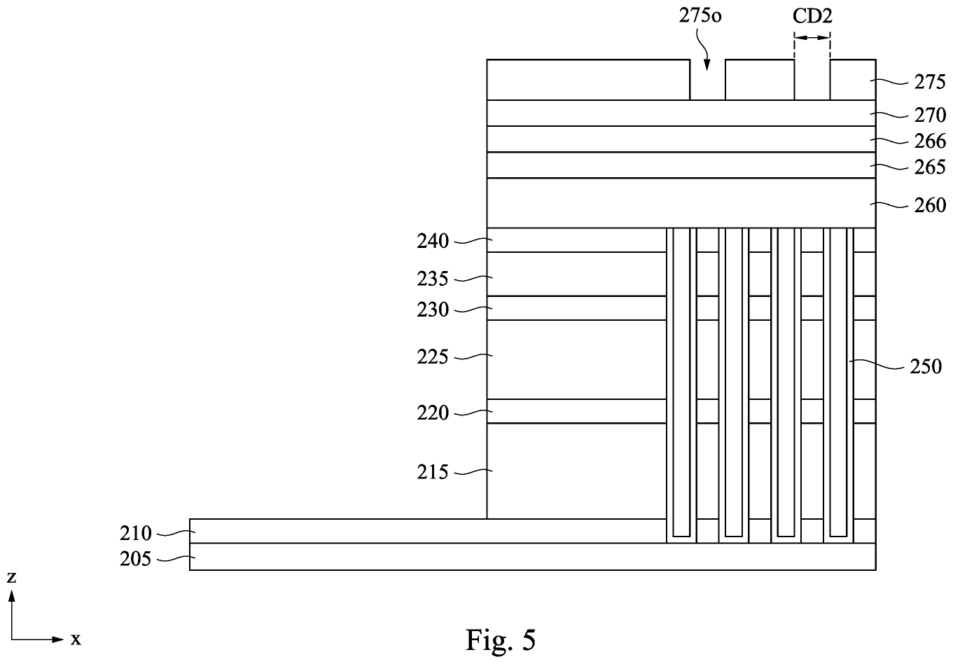

Reference is made to FIG. 5 and FIG. 13. In operation 303, an under-layer anti-reflective coating 270 is formed directly over the dielectric anti-reflective layer 266 and a photoresist layer 275 is directly formed over the under-layer anti-reflective coating. FIG. 5 illustrates a schematic cross-section view of forming the bottom anti-reflective coating 270 and a photoresist layer 275 over the anti-reflective coatings 265 and 266 according to one or more embodiments of the present disclosure. In one or more embodiments of the present disclosure, the anti-reflective coating 270 and photoresist layer 275 are formed by a coating process.

As shown in FIG. 5, the photoresist layer 275 is developed after the photoresist layer 275 is formed over the bottom anti-reflective coating 270, and the developed photoresist layer 275 has a plurality of openings 2750. The openings 2750 are aligned with regions between the bottom electrode plates 250. Each of the openings 2750 has a length CD2 in the direction x.

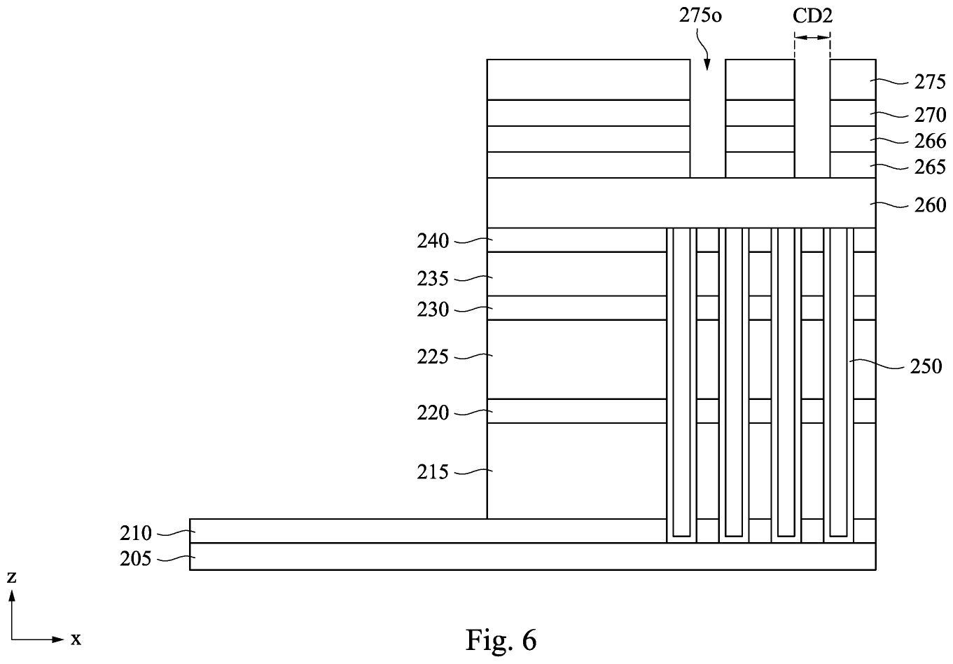

Reference is made to FIGS. 6, 7 and FIG. 13. In operation 304, the carbon film 260 is patterned by the photoresist layer 275.

FIG. 6 illustrates a schematic cross-section view of etching the dielectric anti-reflective layers 265 and 266 according to one or more embodiments of the present disclosure. As shown in FIG. 6, the openings 2750 extend to a top surface of the carbon film 260 through the dielectric anti-reflective layers 265 and 266.

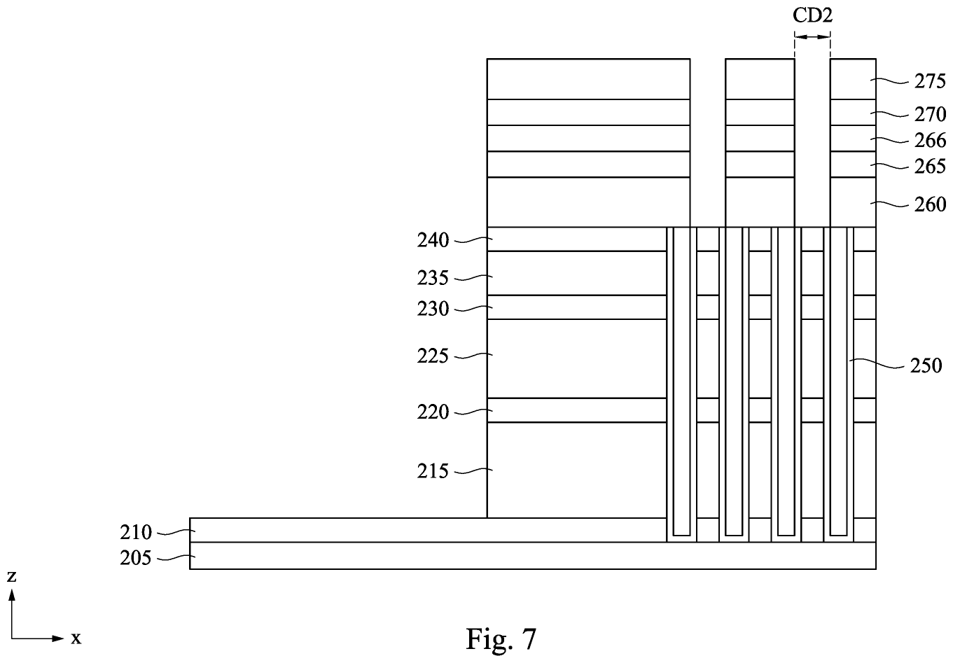

After the dielectric anti-reflective layers 265 and 266 are etched, the carbon film 260 under the dielectric anti-reflective layers 265 and 266 is patterned. FIG. 7 illustrates a schematic cross-section view of patterning the carbon film 260 according to one or more embodiments of the present disclosure.

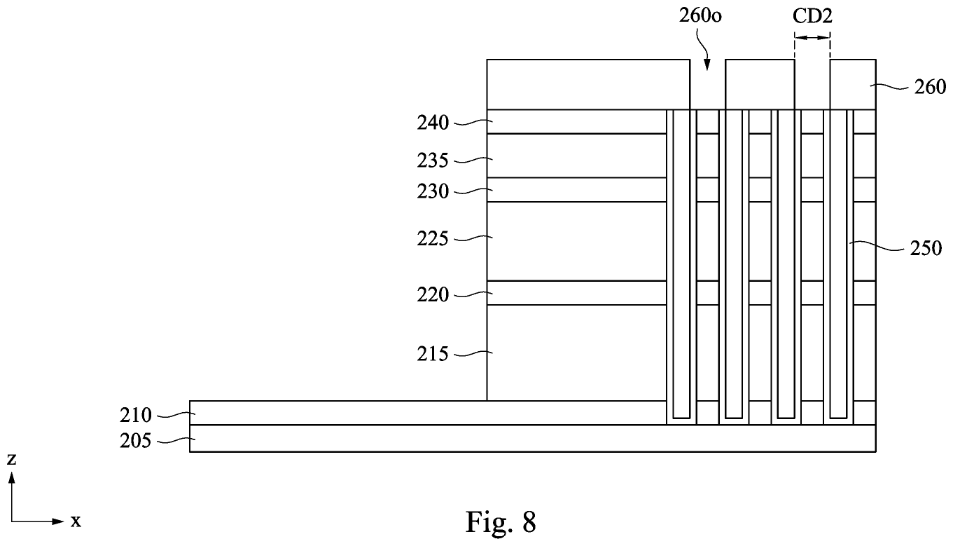

Reference is made to FIG. 8 and FIG. 13. In operation 305, the photoresist layers 275, the anti-reflective coating 270 and the dielectric anti-reflective layers 265, 266 are removed. FIG. 8 illustrates a schematic cross-section view of removal of the photoresist layers, the anti-reflective coating and the dielectric anti-reflective layers according to one or more embodiments of the present disclosure. As shown in FIG. 8, the patterned carbon film 260 has openings 2600 with lengths CD2 in the direction x. The openings 2600 of the carbon film 260 are aligned with regions between the bottom electrode plates 250. The lengths CD2 can be regarded as critical dimensions of the patterned carbon film 260. In one or more embodiments of the present disclosure, the lengths CD2 of each opening 2600 of the carbon film 260 are greater than the length CD1 (as illustrated in FIG. 2B) of each bottom electrode plate 250 in the direction x.

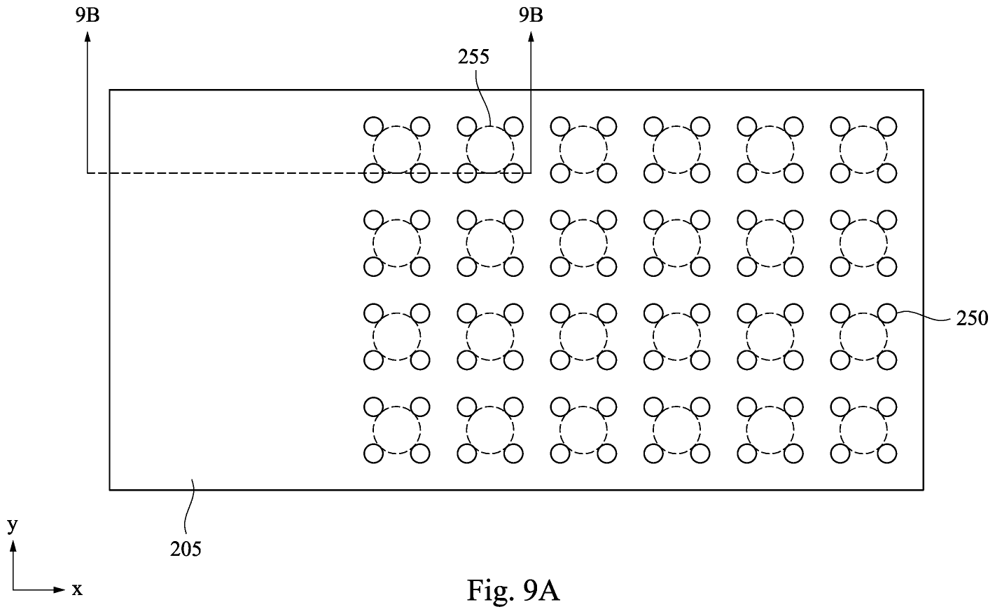

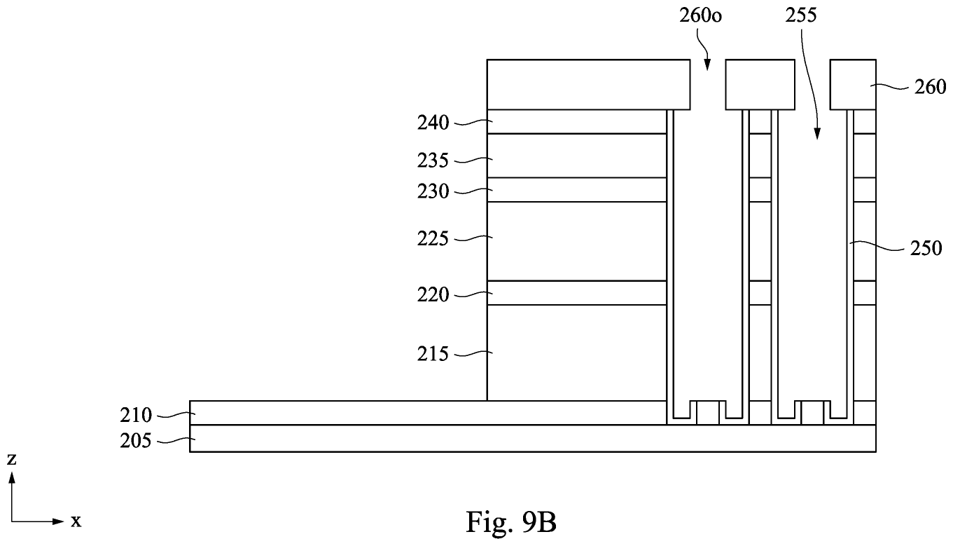

Reference is made to FIGS. 9A-9B and FIG. 13. In operation 306, the bottom electrode plates 250 and the stack of the nitride layers 210, 220, 230, 240 and the oxide layers 215, 225 and 235 are etched to define a plurality of common bottom electrode regions 255 based on the patterned carbon film 260. FIGS. 9A and 9B illustrate a schematic top view and a cross-section view of etching the bottom electrode plates 250, the nitride layers 210, 220, 230, 240 and the oxide layers 215, 225 and 235 by the carbon film 260 according to one or more embodiments of the present disclosure.

As shown in FIG. 9A, a plurality of common bottom electrode regions 255 are formed between immediately adjacent four of the bottom electrode plates 250. For the sake of clarity, the carbon films 260, the nitride layers 210, 220, 230, 240 and the oxide layers 215, 225 and 235 are not illustrated in FIG. 9A.

FIG. 9B illustrates a schematic cross-section view near an edge of the array of the bottom electrode plates 250. For a group of four immediately-adjacent bottom electrode plates 250, the four immediately-adjacent bottom electrode plates 250, the nitride layers 220, 230, 240 and the oxide layers 215, 225 and 235 between the four immediately-adjacent bottom electrode plates 250 are etched to define a common bottom electrode region 255 based on the openings 2600 of the patterned carbon film 260, wherein the patterned carbon film 260 having the openings 2600 may be regarded as a hard mask. Sidewall portions of the immediately adjacent four of the bottom electrode plates 250 are etched. The schematic cross-section view illustrated in FIG. 9B shows one of the common bottom electrode regions 255 is across immediately-adjacent two of the bottom electrode plates 250, wherein the immediately-adjacent two of the bottom electrode plates 250 have etched sidewall portions.

In one or more embodiments of the present disclosure, the bottom electrode plates 250, the nitride layers 220, 230, 240 and the oxide layers 215, 225 and 235 may be etched by three condition dry etch processes. It is noted that based on structural results, the carbon material of the carbon film 260 has enough remaining thickness to prove high protection and etch selectivity ability to under-layer structure including the bottom electrode plates 250 after the three condition dry etch processes are performed. For example, after the bottom electrode plates 250, the nitride layers 220, 230, 240 and the oxide layers 215, 225 and 235 are etched and the common bottom electrode regions 255 are defined, the carbon film 260 may have remaining thickness over 50% of a thickness in which the carbon film 260 has prior to definition of the common bottom electrode regions 255. The etch selectivity, which is a ratio of an etch rate of the carbon film 260 to an etch rate of the oxide layers 215, 225 and 235, may be equal to or greater than 30. The single carbon film 260 deposited under high temperature and having large density endures low strength and shows steady to prevent film crack and storage short.

As an example but not limiting the present disclosure, the thickness of the carbon film 260 may be 149 nm in the direction z after the common bottom electrode regions 255 are defined.

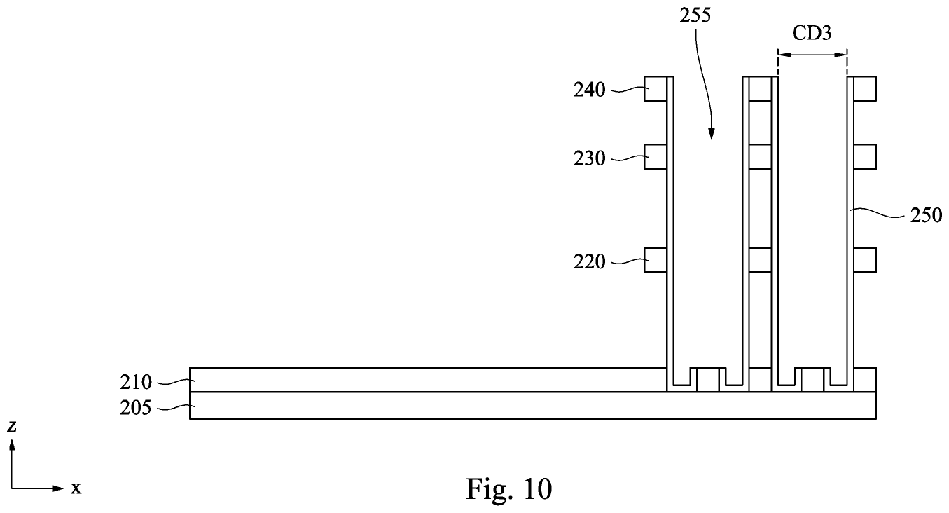

Reference is made to FIG. 10 and FIG. 13. In operation 307, the carbon film 260 and the oxide layers 215, 225 and 235 are removed. FIG. 10 illustrates a schematic cross-section view of removal of the carbon films 260 and the oxide layers 215, 225 and 235 according to one or more embodiments of the present disclosure. In some embodiments of the present disclosure, the carbon film 260 and the oxide layers 215, 225 and 235 may be removed in different processes. After the carbon film 260 and the oxide layers 215, 225 and 235 are removed, the nitride layers 210, 220, 230 and 240 support the bottom electrode plates 250. The array of the bottom electrode plates 250 have critical dimensions of lengths CD3 of the common bottom electrode regions 255 in the direction x. Each length CD3 is greater than length CD2 as illustrated in FIG. 8.

As an example but not limiting the present disclosure, the length CD2 may be 27.4 nm and the length CD3 may be 35 nm. As an example but not limiting the present disclosure, the length CD2 may be 23.8 nm and the length CD3 may be 32 nm.

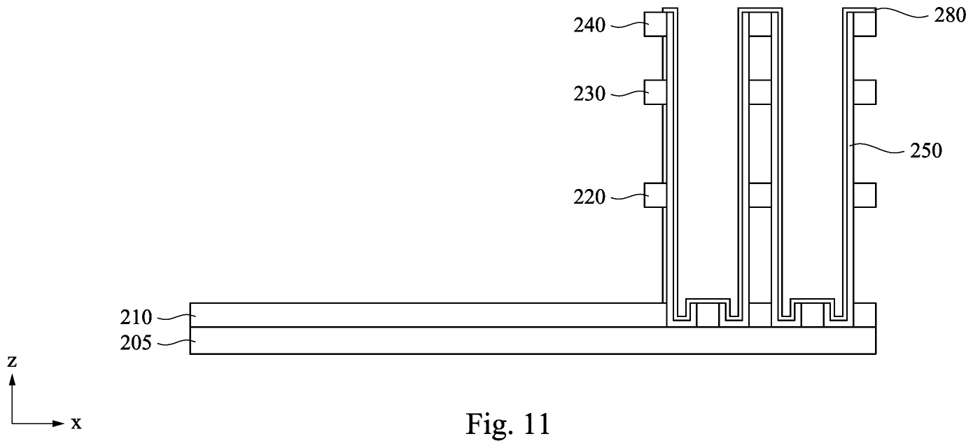

Reference is made to FIG. 11 and FIG. 13. In operation 308, a dielectric layer 280 is deposited over the bottom electrode plates 250. FIG. 11 illustrates a schematic cross-section view of forming the dielectric layer 280 over the bottom electrode plates 250 according to one or more embodiments of the present disclosure. As shown in FIG. 11, the dielectric layer 280 is across numbers of common bottom electrode regions 255 and the bottom electrode plates 250. In one or more embodiments of the present disclosure, the dielectric layer 280 may be high-k dielectric material.

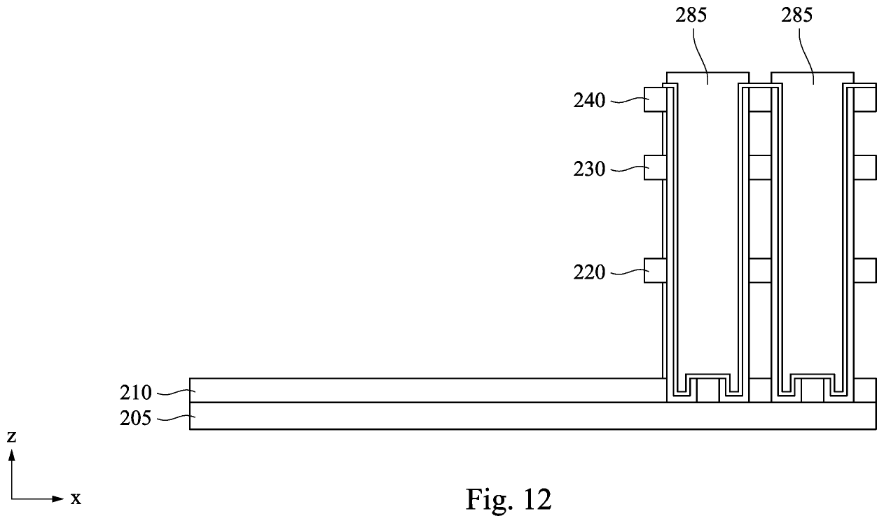

Reference is made to FIG. 12 and FIG. 13. In operation 309, a plurality of top electrode plates 285 is formed over the dielectric layer 280 and filled with the bottom electrode plates 250. FIG. 12 illustrates a schematic cross-section view of forming the top electrode plates 285 over the high-k dielectric layer 280 according to one or more embodiments of the present disclosure, wherein the top electrode plates 285 are formed over the common bottom electrode regions 255 between the bottom electrode plates 250. As shown in FIG. 12, one of the top electrode plates 285 is across two immediately-adjacent two of the bottom electrode plates 250 in the direction x. The bottom electrode plates 250, the dielectric layer 280 and the top electrodes 285 form a plurality of capacitors of a capacitor structure 200, wherein the formed capacitors share the same dielectric layer 280, and each of the formed capacitors has one of the top electrode plate 285 and immediately-adjacent four of the bottom electrode plates connected to each other by the dielectric layer 280 in the corresponding common electrode region 255.

In summary, in one or more embodiments of the present disclosure, less numbers of carbon films are used as hard masks for etching under-layer structure. For example, a single carbon film may be used as the hard mask. In one or more embodiments of the present disclosure, the single carbon film may be deposited at high temperature and have great density, modulus and etch selectivity with respect to oxide. Less stress accumulation phenomenon appears on the under-layer structure under the single carbon film, and it avoids expected crack and damage for the under-layer structure including bottom electrode plates under the single carbon film during formation of capacitor structures.

Although the embodiments of the present disclosure have been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the embodiments of the present disclosure without departing from the scope or spirit of the present disclosure. In view of the foregoing, it is intended that the present disclosure cover modifications and variations of this disclosure provided they fall within the scope of the following claims.

What is claimed is:

1. A method of forming a capacitor structure, comprising:
depositing a single carbon film over tops of bottom electrode plates;
patterning the single carbon film;
etching the bottom electrode plates based on the single carbon film after the single carbon film is patterned;
removing the single carbon film after the bottom electrode plates are etched;
forming a dielectric layer over the bottom electrode plates; and
forming a plurality of top electrode plates over the dielectric layer and aligned with the bottom electrode plates.

2. The method of claim 1, wherein the single carbon film is deposited by a plasma-enhanced chemical vapor deposition process at a temperature in a range between 600° C. and 650° C.

3. The method of claim 1, further comprising:
depositing a first dielectric anti-reflective layer over the single carbon film; and
depositing a second dielectric anti-reflective layer directly over the first dielectric anti-reflective layer.

4. The method of claim 3, wherein the first dielectric anti-reflective layer and the second dielectric anti-reflective layer are deposited by chemical vapor deposition processes.

5. The method of claim 3, wherein the first dielectric anti-reflective layer and the second dielectric anti-reflective layer are silicon oxynitride and have different compositions of oxygen and silicon.

6. The method of claim 3, further comprising:
forming an anti-reflective coating over the second dielectric anti-reflective layer; and
forming a photoresist layer over the anti-reflective coating, wherein the anti-reflective coating and the photoresist layer are formed by coating processes, and patterning the single carbon film comprises etching the single carbon film by the photoresist layer.

7. The method of claim 1, wherein the bottom electrode plates are formed within a stack of nitride layers and oxide layers, etching the bottom electrode plates comprises:
etching the nitride layers and the oxide layers to a top surface of the lowest nitride layer.

8. The method of claim 7, wherein an etch selectivity of the single carbon film and the oxide layers is equal to or greater than 30.

9. The method of claim 1, wherein each of the bottom electrode plates has a U-shape profile with a bottom portion connected to a conductive layer, etching the bottom electrode plates comprises etching sidewall portions of immediately-adjacent two of the bottom electrode plates to define a common bottom electrode region.

10. A method of forming a capacitor structure, comprising:
depositing a carbon film over a stack of nitride layers and oxide layers and a plurality of bottom electrode plates within the stack of the nitride layers and the oxide layers, wherein the carbon film has compressive stress;
patterning the carbon film;
etching the bottom electrode plates and the stack of the nitride layers and the oxide layers based on the carbon film after the carbon film is patterned;
removing the carbon film after the bottom electrode plates and the stack of the nitride layers and the oxide layers are etched;
removing the oxide layers;
forming a dielectric layer over the bottom electrode plates; and
forming a plurality of top electrode plates over the dielectric layer and aligned with the bottom electrode plates.

11. The method of claim 10, wherein the carbon film is deposited by a plasma-enhanced chemical vapor deposition process at a temperature in a range between 600° C. and 650° C.

12. The method of claim 10, further comprising:
depositing a first dielectric anti-reflective layer over the carbon film; and
depositing a second dielectric anti-reflective layer directly over the first dielectric anti-reflective layer.

13. The method of claim 12, further comprising:
forming an anti-reflective coating over the second dielectric anti-reflective layer; and
forming a photoresist layer over the anti-reflective coating, wherein the anti-reflective coating and the photoresist layer are formed by coating processes, and patterning the carbon film comprises etching the carbon film by the photoresist layer.

14. The method of claim 10, wherein an etch selectivity of the carbon film and the oxide layers is equal to or greater than 30.

15. The method of claim 10, wherein each of the bottom electrode plates is a hollow tube with a U-shape profile, and each of the top electrode plates is filled with immediate-adjacent two of the bottom electrode plates.

16. A method of forming a capacitor structure, comprising:
depositing a carbon film over a plurality of bottom electrode plates;
depositing a first dielectric anti-reflective layer over the carbon film;
depositing a second dielectric anti-reflective layer directly over the first dielectric anti-reflective layer, wherein the first dielectric anti-reflective layer and the second dielectric anti-reflective layer have different compositions of oxygen and silicon;
forming an anti-reflective coating over the second dielectric anti-reflective layer;
forming a photoresist layer over the anti-reflective coating;
patterning the carbon film by the photoresist layer;
etching the bottom electrode plates based on the carbon film after the carbon film is etched;
forming a dielectric layer over the bottom electrode plates after the bottom electrode plates are etched; and
forming a plurality of top electrode plates over the dielectric layer and aligned with the bottom electrode plates.

17. The method of claim 16, wherein each of the top electrode plates is formed over a common bottom electrode region across at least two of the bottom electrode plates.

18. The method of claim 16, wherein the anti-reflective coating and the photoresist layer are formed by coating processes.

19. The method of claim 16, wherein depositing the carbon film over the bottom electrode plates comprises depositing the carbon film over a stack of oxide layers and nitride layers around the bottom electrode plates.

20. The method of claim 16, wherein the carbon film is deposited by a plasma-enhanced chemical vapor deposition process at a temperature in a range between 600° C. and 650° C.
